(19) United States
(12) Patent Application Publication
(10) Pub. No.: US 2010/0108362 A1
(43) Pub. Date: May 6, 2010

(54) ELECTRONIC SYSTEM WITH HEAT DISSIPATION DEVICE

(75) Inventors: JUAN DU, Shenzhen City (CN); CUI-JUN LU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/436,781

(22) Filed: May 7, 2009

(30) Foreign Application Priority Data
Nov. 6, 2008 (CN) 200810305409.9

(51) Int. Cl. H05K 1/00

(52) U.S. Cl. 174/252

(57) ABSTRACT

An electronic system includes a printed circuit board, a base, and a wire clip. The printed circuit board includes an electronic component and a plurality of hooks around the electronic component. The base thermally contacts the electronic component of the printed circuit board. Two clasps are formed at opposite ends of the base. The wire clip includes two pressing portions, two first connecting portions extending inwardly from first ends of the two pressing portions respectively, and two second connecting portions extending inwardly from second ends of the two pressing portions respectively. The first and second ends of the pressing portion are opposite. The pressing portions of the wire clip are clasped by the clasps of the base. The first connecting portions engage with two hooks of the printed circuit board, and the second connecting portions engage with another two hooks of the printed circuit board.

### BACKGROUND

1. Technical Field

The present disclosure relates to an electronic system with a heat dissipation devices and, particularly, to an electronic system with a heat sink capable of being conveniently assembled to and disassembled from a printed circuit board.

2. Description of Related Art

A heat sink is usually placed in thermal contact with a heat generating electronic device, which is mounted on a printed circuit board (PCB), such as a central processing unit (CPU), and transfers heat through conduction away from the heat generating electronic device so as to prevent over-heating of the heat generating electronic device.

Conventionally, the heat sink and the PCB are assembled together by a number of screws. The screws may be assembled to and disassembled from the heat sink and the PCB one by one. This is very time-consuming and trouble. The PCB is prone to be destroyed by assembling or disassembling the heat sink repeatedly.

What is needed, therefore, is a heat dissipation device overcoming the above-described problems.

### BRIEF DESCRIPTION OF THE DRAWINGS

FIG. 1 is an exploded, isometric view of an electronic system in accordance with an embodiment of the present disclosure.

FIG. 2 is a partly assembled view of the electronic system in FIG. 1.

FIG. 3 is an assembled view of the electronic system in FIG. 1.

### DETAILED DESCRIPTION

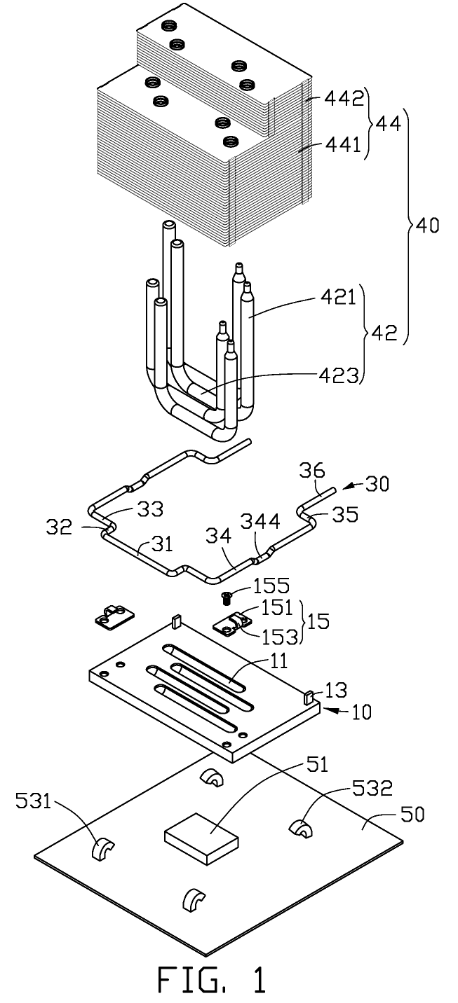

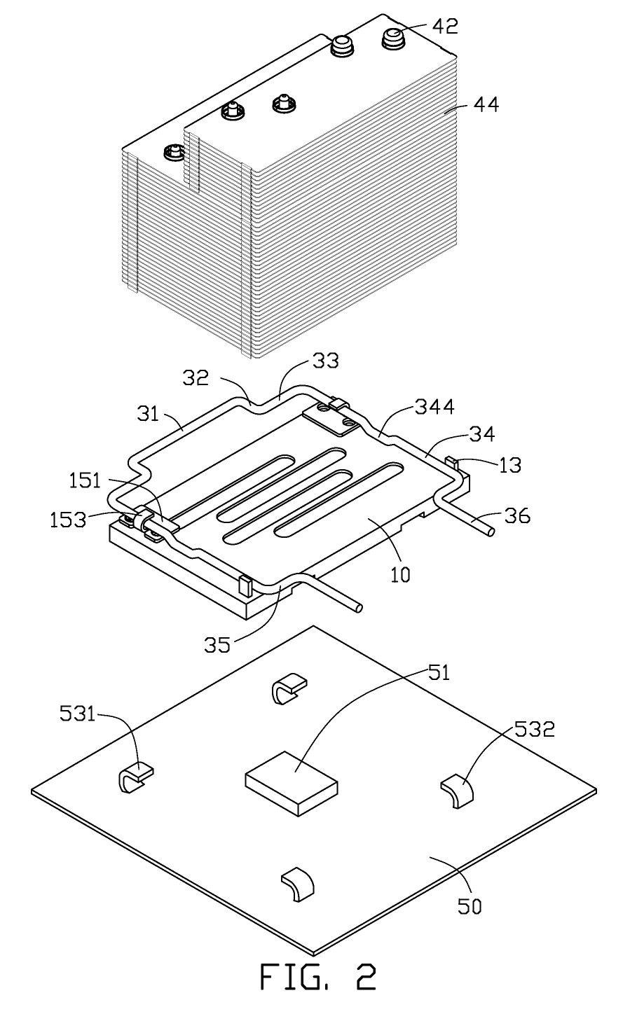

Referring to FIGS. 1-2, an electronic system of the present disclosure comprises a printed circuit board 50 (PCB) and a heat dissipation device (not labeled) thermally contacting the PCB 50. The PCB 50 comprises an electronic component 51, two first hooks 531 and two second hooks 532 around the electronic component 51. The heat dissipation device comprises a base 10 contacting the electronic component 51, a heat sink 40 mounted on a top surface of the base 10, a wire clip 30 is mounted on the base 10 and engaging with two first hooks 531 and two second hooks 532 which are around the electronic component 51 of the PCB 50.

The heat sink 40 comprises a fin group 44 and four U-shaped heat pipes 42. The fin group 44 is located at the top surface of the base 10. The heat pipes 42 extend through the fin group 44 and are thermally connected to the base 10.

The fin group 44 comprises a number of first fins 441 and a number of second fins 442. The first and second fins 441, 442 are substantially parallel to each other and engage with each other via locking members (not labeled) formed at corners thereof. Air passages are defined between the first and second fins 441, 442. Each of the first fins 441 and the second fins 442 is a rectangular sheet. A length of the second fin 442 is equal to that of the first fin 441. A width of the second fin 442 is smaller than that of the first fin 441. The second fins 442 are located at top of the first fins 441. Right ends of the second fins 442 and right ends of the first fins 441 are coplanar. Thus, the first fins 441 and the second fins 442 cooperatively form an L-shaped configuration.

Each of the heat pipes 42 comprises two parallel heat-conductive sections 421 and a connecting section 423 interconnecting the two heat-conductive sections 421. Four heat-conductive sections 421 of the two heat pipes 42 extend through the first and second fins 441, 442 from bottom to top. Four heat-conductive sections 421 of another two heat pipes 42 extend through the first fins 441 from bottom to top and are located beside the second fins 442. The connecting sections 423 are located at a bottom end of the fin group 44.

The base 10 is made of aluminum or copper. The top surface of the base 10 defines four parallel grooves 11 to receive the connecting sections 423 of the four heat pipes 42. First and third grooves 11 are located near a right end of the base 10, as viewed from FIG. 1. Second and fourth grooves 11 are located near a left end of the base 10. Two baffling portions 13 extend upwardly from the right and left ends of a rear side of the base 10, respectively. The two baffling portions 13 restrict the wire clip 30 therebetween. Two engaging portions 15 are mounted on the right and left ends of a front side of the base 10, respectively. The engaging portion 15 comprises a rectangular mounting plate 151 and an L-shaped clasp 153 extending from a central portion of a lateral side of the mounting plate 151. Two screws 155 extend through the mounting plate 151 and engage with the base 10 to mount the engaging portion 15 on the base 10. The clasp 153 and the mounting plate 151 cooperatively define a U-shaped opening therebetween to receive the wire clip 30. The two engaging portions 15 are mounted on the right and left ends of the base 10 with the two openings thereof facing to each other. The two clasps 153 of the two engaging portions 15 restrict the wire clip 30 therebetween.

The clip 30 is integrally made of a metal wire. The clip 30 comprises a first straight connecting portion 31, two straight extending portions 32, two straight second connecting portions 33, two bended pressing portions 34, two straight third connecting portions 35 and two operating portions 36. One extending portion 32, second connecting portion 33, pressing portion 34, third connecting portion 35 and operating portion 36 are connected to one end of the first connecting portion 31 in series. Similarly, the other extending portion 32, second connecting portion 33, pressing portion 34, third connecting portion 35 and operating portion 36 are connected to another end of the first connecting portion 31 in series.

The extending portions 32 perpendicularly extend from opposite ends of the first connecting portion 31. The first connecting portion 31 and the two extending portions 32 form a U-shaped configuration. The two second connecting portions 33 perpendicularly extend outwardly from rear ends of the two extending portions 32, respectively, and are oriented toward opposite directions. The two pressing portions 34 extend rearwards from free ends of the two second connecting portions 33 respectively. The two third connecting portions 35 extend inwardly from two free ends of the two pressing portions 34. The two operating portions 36 extend perpendicularly and rearwards from two free ends of the two third connecting portions 35 respectively.

Each of the pressing portion 34 includes a first section close to the second connecting portions 33, a second section close to the third connecting portions 35, and a downward protruded portion 344 connected between the first and second sections. When the clip 30 is assembled to the base 10, the two first sections of the two opposite pressing portions 34 engage with the two clasps 153 of the two engaging portions 15 of the base 10, and the two second sections thereof are restricted between the two baffling portions 13 of the base 10. Thus, the two pressing portions 34 of the clip 30 are restricted regarding lateral movement thereof.

The first hooks 531 of the printed circuit board 50 engage with the two second connecting portions 33 of the wire clip 30 and the second hooks 532 engage with the two third connecting portions 35. The two first hooks 531 are positioned at a front side of the PCB 50, and the two second hooks 532 are positioned at a rear side of the PCB 50. When the assembly of the clip 30 and the base 10 is assembled to the PCB 50, the two first hooks 531 clasp the two second connecting portions 33 and the two second hooks 532 clasp the two third connecting portions 35. As a result, the assembly of the clip 30 and the base 10 is fixed on the PCB 50.

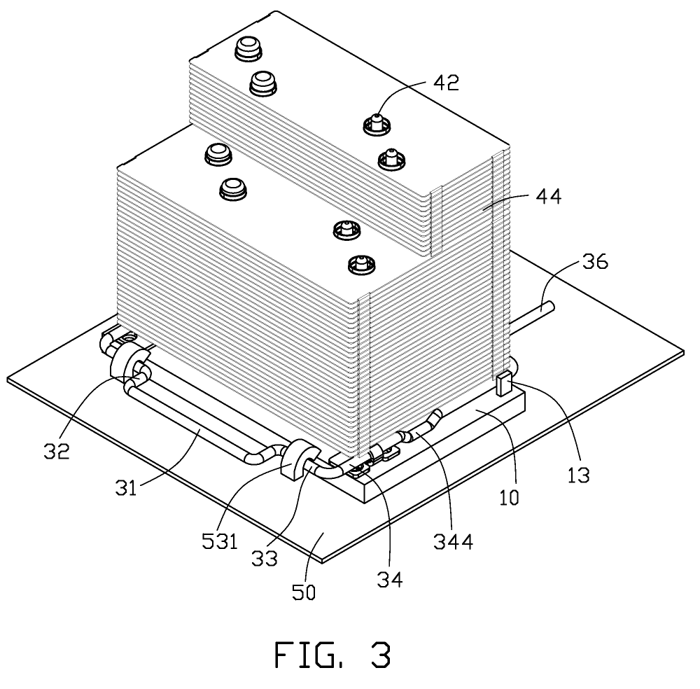

Referring to FIG. 3 also, in assembling, the operating portions 36 are pressed inwardly to enable the pressing portions 34 of the wire clip 30 be sandwiched between the clasps 153 of the engaging portions 15 and the baffling portions 13. Thereafter, the operating portions 36 are released, and the first sections of the pressing portions 34 enter the clasps 153 of the engaging portions 15 and the second sections of the pressing portions 34 abut against the baffling portions 13 due to the resilience of the pressing portions 34. The protruded portion 344 of the pressing portion 34 abuts against the top surface of the base 10. Thus, the base 10 and the wire clip 30 are assembled together.

The heat-conductive sections 421 of the heat pipes 42 extend through the fin group 44 and the connecting sections 423 of the heat pipes 42 are received in the grooves 11 of the base 10. Thus, the heat sink 40 is mounted on the base 10. The base 10 thermally contacts with the electronic component 51 of the PCB 50. The second connecting portions 33 of the clip 30 are clasped by the two first hooks 531 of the PCB 50. The operating portions 36 of the clip 30 are pressed inwardly and downwardly until the third connecting portions 35 of the clip 30 are located at lower portions of the two second hooks 532 of the PCB 50. The operating portions 36 are released, and the third connecting portions 35 are clasped by the two second hooks 532. Therefore, the electronic system is assembled completely.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An electronic system comprising:
a printed circuit board having an electronic component and a plurality of hooks around the electronic component;
a base thermally contacting the electronic component of the printed circuit board, two clasps formed at opposite ends of the base; and
a wire clip comprising two pressing portions, two first connecting portions extending inwardly from first ends of the two pressing portions respectively, and two second connecting portions extending inwardly from second ends of the two pressing portions respectively, the first and second ends of the pressing portion being opposite;
wherein the pressing portions of the wire clip are clasped by the clasps of the base, the first connecting portions engage with two hooks of the printed circuit board, and the second connecting portions engage with another two hooks of the printed circuit board.

2. The electronic system as claimed in claim 1, wherein two baffling portions are formed at opposite ends of the base and abut against the pressing portions of the wire clip to restrict the wire clip therebetween.

3. The electronic system as claimed in claim 1, wherein a central portion of the pressing portion is punched to form a protruded portion to press the base.

4. The electronic system as claimed in claim 1, wherein the wire clip further comprises two operation portions extending outwardly from free ends of the second connecting portions respectively.

5. The electronic system as claimed in claim 4, wherein a U-shaped first connecting portion connects the first connecting portions of the wire clip and extends outwardly from the first connecting portions.

6. The electronic system as claimed in claim 1, wherein a fin group is located at a top of the base.

7. The electronic system as claimed in claim 6, wherein a heat pipe extends through the fin group and is secured on the base.

8. The electronic system as claimed in claim 1, wherein a mounting plate is mounted on the base and the clasp extends from a side of the mounting plate.

9. The electronic system as claimed in claim 1, wherein the printed circuit board comprises two first hooks positioned at a side of the printed circuit board and two second hooks positioned another side of the printed circuit board, the first hooks engage with the two first connecting portions and the two second hooks engage with the two second connecting portions.
